(19) United States
(12) Patent Application Publication
(10) Pub. No.: US 2005/0281950 A1
(43) Pub. Date: Dec. 22, 2005

(54) Deposition apparatus and method

(75) Inventors: Atsushi Tanaka, Minamiashigara-shi (JP); Takatoshi Tsujimura, Fujisawa-shi (JP); Koji Murayama, Yasu-gun (JP)

Correspondence Address: MILDE & HOFFBERG, LLP, 10 BANK STREET, SUITE 460, WHITE PLAINS, NY, 10606, US

(73) Assignees: CHI MEI OPTOELECTRONICS CORP.; KYOCERA CORPORATION

(21) Appl. No.: 11/154,408

(22) Filed: Jun. 16, 2005

(30) Foreign Application Priority Data
Jun. 18, 2004 (JP) 2004-181207

(51) Int. Cl. C23C 16/00

(52) U.S. Cl. 427/248.1; 118/719; 118/726

(57) ABSTRACT

A deposition apparatus 10a of this invention include an evaporation source 12 for evaporating materials by heating to deposit evaporant on a plurality of substrates 14, wherein the evaporation source 12 is able to move near to at least two of the substrates 12.

### BACKGROUND OF THE INVENTION

1. Field of the Invention

The present invention relates to a deposition apparatus and a method for depositing evaporant.

2. Description of Related Art

Conventional organic layers of an organic light emitting display (OLED) are formed by laminating organic materials using an evaporation method or an ink jet method. The evaporation method is used when organic materials are low-molecular. On the other hand, the ink jet method is used when organic materials are high-molecular.

It is necessary to heat organic materials, such as Alq₃ in a vacuum chamber with an evaporation source (heating source) to perform evaporation. However, it is difficult to rapidly switch between the stop/start of evaporating the organic materials. There is a possibility of the organic materials being bumped or thermally transformed as a result of big temperature changes. Thus, the organic materials are constantly heated when the production line of OLEDs gets started.

The constant heating of organic materials wastes the materials even while a substrate is loaded into and is unloaded from a vacuum chamber. In addition to the high costs of the organic materials of OLEDs, the usability in the production process becomes very low. This causes a rise in production costs of OLEDs.

A method for improving the usability of the organic materials has been, therefore, considered. For example, a method for moving a linear or a point evaporation source keeping a short distance from the substrate in accordance with the substrate surface is known.

Cited document 1 discloses a method for depositing a film, in which an alignment processing time for a cluster-type deposition apparatus can be shortened in a vacuum chamber and wasteful consumption of organic materials can be suppressed, by the alignment of outside the vacuum chamber.

(Cited Document 1)

Japanese Publication No. 2002-367781

Even in the case of using the former method, materials for the evaporation source are continuously evaporated at the waiting time before changing a substrate or aligning a metal mask, so that the ratio of the materials evaporated at the time other than actually performing evaporation is too high to be ignored. Accordingly, it is impossible to avoid a rise in production costs even when using these techniques.

Further, even in the case of using the latter method, that is, a method disclosed in the Cited document 1, wasteful consumption of materials occurs because materials for an evaporation source are continuously evaporated when a substrate is loaded into and is unloaded from a vacuum chamber.

It is, therefore an object of the present invention to provide a deposition apparatus and a deposition method to minimize wasteful consumption of materials.

### SUMMARY OF THE INVENTION

A deposition apparatus according to the present invention comprises: at least one vacuum chamber where a plurality of substrates are arranged; and an evaporation source for evaporating materials by heating to deposit evaporant on each substrate, wherein the evaporation source is able to move near to at least two of the substrate.

A deposition method according to the present invention comprises the steps of: preparing a substrate; arranging an evaporation source near an one of the substrates; moving the evaporation source from one substrate to near an another of the substrates; and evaporating the materials by hearting to deposit evaporant on the another substrate.

### BRIEF DESCRIPTION OF THE DRAWING

FIG. 1 shows a configuration of a deposition apparatus of the present invention.

FIG. 2 shows another configuration of the deposition apparatus of the present invention having 3 vacuum chambers.

FIG. 3 shows still further configuration of the deposition apparatus of the present invention using a linear evaporation source.

FIG. 4 shows further configuration of the deposition apparatus of the present invention where point evaporation sources are transferred.

### DESCRIPTION OF THE PREFERRED EMBODIMENTS

Embodiments of the present invention will now be described in detail below with reference to accompanying drawings. Organic materials, such as Alq₃ for OLED are used to be evaporated (deposited) on each substrate in a deposition apparatus.

In the deposition apparatus according to the present invention, evaporant is deposited on a plurality of substrates. The deposition apparatus includes an evaporation source for being alternately or sequentially transferred on the upper side of the substrates (the upper side is the surface side of each substrate where the evaporant is deposited) and evaporating materials by heating to deposit the evaporant on each substrate. Examples of evaporation sources are resistance heating evaporation sources, electron beam evaporation sources, and induction heating evaporation sources, or the like. Examples are described respectively below. In addition, FIGS. 1 to 4 show respectively the movement of substrates 14 with a heavy arrow line and the movement of an evaporation source 12 with a thin arrow line.

### EXAMPLE 1

In FIG. 1, a deposition apparatus 10a comprises: a plurality of vacuum chambers A and C where evaporation is performed; a path B for spatially connecting between the vacuum chambers A and C where an evaporation source 12 passes through; and means for transferring the evaporation source 12.

The path B keeps having a similar air pressure to the vacuum chambers A and C. Accordingly, evaporation can be started soon after the evaporation source 12 passes through the path B. In FIGS. 1 to 4, the path B is indicated by a line, but the path B is space kept in high-vacuum.

The deposition apparatus 10a further comprises: a transfer work chamber 16 including a robot arm for loading/unloading the substrate 14 into and from the vacuum chambers A and C; a substrate loading chamber 18 for loading the substrate 14 into the transfer work chamber 16; and a substrate unloading chamber 20 for unloading the substrate 14 from the transfer work chamber 16. The transfer work chamber 16 or the like functions as a vacuum spare chamber. Further, each of the vacuum chambers A and C includes means for aligning masks with the substrates 14. A plurality of deposition apparatuses 10a may be configured so that the substrate unloading chamber 20 and the substrate loading chamber 18 can be connected to deposit a plurality of materials on one substrate 14.

The means for transferring the evaporation source 12 comprises: a rail; and a slider for being led by the rail to support the evaporation source 12.

In the deposition apparatus 10a, the vacuum chambers A and C are connected by the path B. A rail is arranged among the vacuum chambers A, C, and the path B. The rail is arranged so that the evaporation source 12 can reciprocate between the vacuum chambers A and C. The evaporation source 12 is transferred among the vacuum chambers A and C, and the path B together with the slider.

A gate valve for spatially separating/connecting the vacuum chambers A and C may be provided. For example, a gate valve is provided at the junction between the vacuum chambers A and the path B. The vacuum chambers A and C can be connected or separated via the path B by opening or closing the gate valve. In the case of closing the gate valve, the deposition apparatus 10a is configured so that each of the vacuum chambers A and C can be independently evacuated. More specifically, a pump for vacuum pumping is equipped with each of the vacuum chambers A and C. Evaporation can be performed only in one workable vacuum chamber out of the vacuum chambers A and B by closing the gate valve when either the vacuum chambers A or C is broken down.

Next, an evaporation process using the deposition apparatus 10a in FIG. 1 will be described. Table 1 shows an evaporation process of the deposition apparatus 10a. Arrow marks indicated in Table 1 show the movement of the evaporation source 12. It is not shown in Table 1, but evaporation shown in Table 1 is performed after providing the substrate 14 and the evaporation source 12. In examples described later, evaporation is performed in the same manner as in Table 1.

TABLE 1

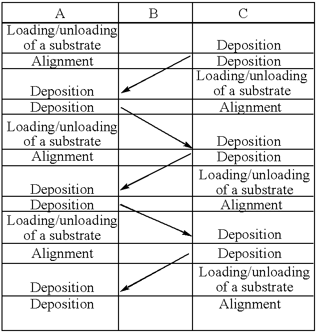

As shown in Table 1, when the evaporation source 12 is located in the vacuum chamber C, the substrate 14 within the vacuum chamber C is evaporated. Then the substrate 14 is loaded into and unloaded from the vacuum chamber A, and is aligned with a mask. The alignment is to adjust the position between the substrate 14 and the mask to perform evaporation at a desired position.

Upon completion of evaporation in the vacuum chamber C, the evaporation source 12 is transferred to the vacuum chamber A via the path B from the vacuum chamber C. Alignment is completed in the vacuum chamber A when the evaporation source 12 is transferred to the vacuum chamber A and evaporation is started immediately after that.

The substrate 14 is loaded into and is unloaded from the vacuum chamber C and is then aligned with the mask when the evaporation source 12 is transferred from the vacuum chamber C to the vacuum chamber A to perform evaporation in the vacuum chamber A.

As mentioned above, a plurality of substrates 14 are evaporated in order. The waiting time of the evaporation source 12 is as shortened as possible by adjusting the duration of evaporation time in the vacuum chambers A and C and the duration of loading and unloading of the substrate 14. For example, the duration of evaporating the substrates 14 is lengthened when it takes time to load the substrate 14 from the vacuum chamber A into the vacuum chambers C and to unload the substrate 14 from the vacuum chamber C.

As described above, the evaporation source 12 is transferred to and from a plurality of vacuum chambers A and C. More specifically, the evaporation source 12 is transferred to one vacuum chamber C (A) to deposit the substrates 14 within the vacuum chamber C (A) when the loading and unloading or alignment of the substrate 14 is performed in another chamber A (C). Accordingly, it becomes possible to divert time to wastefully evaporate materials for the evaporating source 12 to time to evaporate on another substrates 14 when loading/unloading the substrate 14 or aligning the substrate 14 and the mask, so that the amount of the wasteful evaporant may be minimized during the production processes. In other words, the wasteful consumption of organic materials for the evaporation source 12 is minimized because unnecessary material consumption is extremely minimized while constantly being evaporated. Accordingly, this improves the usability of the materials, which leads to significant effects in improvement of the productivity and reduction of production costs. Further, the shortening of the time for passing the evaporation source 12 through the path B makes the wasteful consumption of materials further minimized.

In this case, the usability of the materials can be improved without switching the stop/start of the evaporation of the evaporation source 12. Accordingly, it is not needed to change the temperature of the evaporation source 12 significantly, and the temperature of the evaporation source 12 is kept almost at a constant temperature, so that there is a few danger of the materials being bumped and thermally transformed.

### EXAMPLE 2

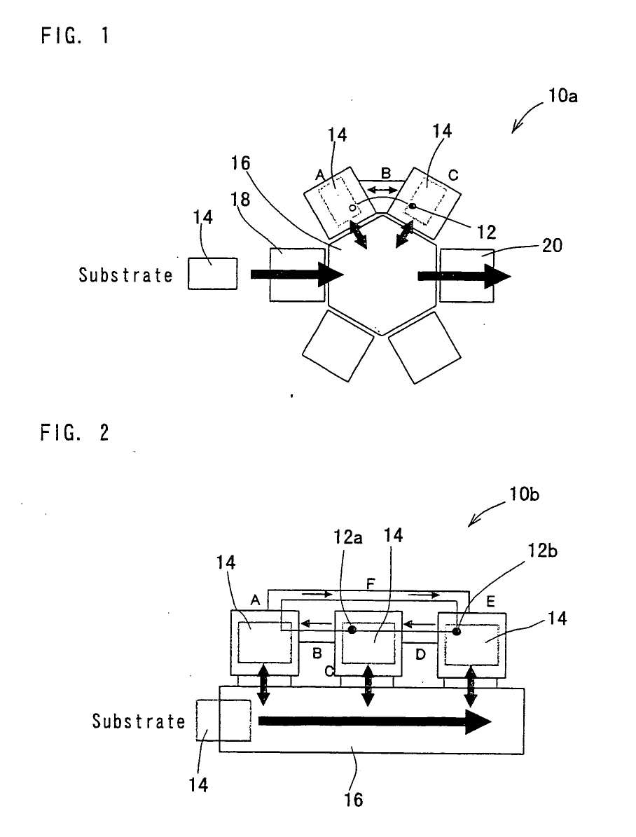

Two vacuum chambers A and C are used in Example 1, but as shown in FIG. 2, three vacuum chambers A, C, and E may be used. A deposition apparatus 10b shown in FIG. 2 is a little different from the deposition apparatus 10a shown in FIG. 1, but basically comprises similar components. That is, the deposition apparatus 10b comprises: a plurality of vacuum chambers A, C, and E; paths B,:D, and F; and a transfer work chamber 16.

Since the number of the vacuum chambers has increased to three, such as the vacuum chambers A, C, and E, three paths B, D, and F are arranged. Means for transferring evaporation sources 12a and 12b is similar to that in Example 1. As is indicated by an arrow mark in FIG. 2, the evaporation sources 12a and 12b cycle among the vacuum chambers A, C, and E. One loop is, therefore, formed by the vacuum chambers A, C, and E, and paths B, D, and F. Respective evaporation sources 12a and 12b may be more than two because of circulating among the vacuum chambers A, C, and E. For example, two evaporation sources may be used as shown in FIG. 2. A plurality of materials may be sequentially evaporated in the same vacuum chamber A (C, E) by using different materials to be evaporated. Further, the materials to be evaporated by each of the evaporation sources 12a and 12b may be the same.

The deposition method using the deposition apparatus 10b in FIG. 2 will now be described in detail. Table 2 shows evaporation processes in the deposition apparatus 10b. Arrow marks indicated by a solid line show the evaporation source 12a and the arrow marks indicated by a dotted line show the evaporation source 12b.

TABLE 2

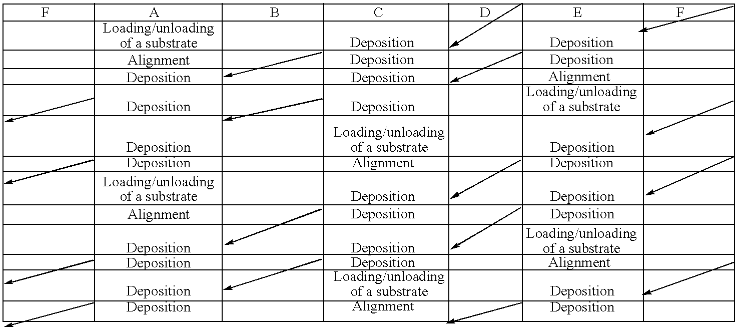

As shown in Table 2, evaporation is sequentially performed on a plurality of substrates 14. Like Example 1, when the substrate 14 is loaded into and is unloaded from the vacuum chamber A or the substrate 14 and a mask are aligned, evaporation is performed in other vacuum chambers such as the vacuum chambers C and E. To prevent different materials from being mixed, a plurality of the evaporation sources 12a and 12b are transferred while synchronizing to have a spacing and then the materials are evaporated. This minimizes wasteful consumption of the materials in the same manner as in Example 1.

### EXAMPLE 3

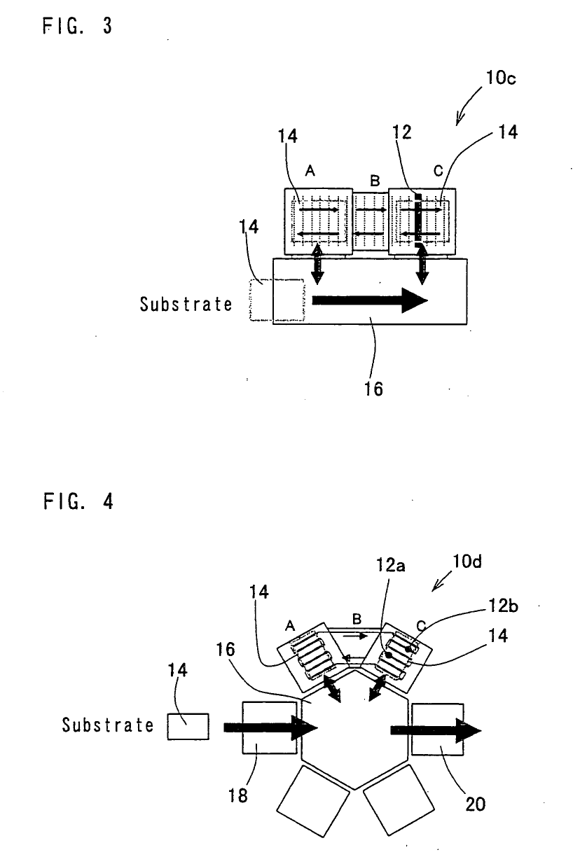

FIG. 3 shows a deposition apparatus 10c using a linear evaporation source 12. Unlike Example 1, the evaporation source 12 is a linear evaporation source. Dotted lines in FIG. 3 show the movement of the evaporation source 12. The deposition apparatus 10c is configured similar to the deposition apparatus 10a in FIG. 1 except the linear evaporation source 12 and the linear evaporation source 12 moves back and forth to the vacuum chambers A and C. The evaporation processes in this deposition apparatus 10c are omitted because of being basically the same as those of Table 1.

Like Example 1 or the like, When the substrate 14 is loaded into and is unloaded from the substrate work chamber 16 or the substrate 14 and the mask are aligned in the same vacuum chamber A (C), evaporation is performed in another vacuum chamber C (A). Accordingly, production costs of OLED can be reduced because of few wasteful consumption of the materials.

### EXAMPLE 4

FIG. 4 shows a deposition apparatus 10d in which the point evaporation sources 12a and 12b move to and from a desired position at the upper portion of the substrates 14. In the apparatus 10d in FIG. 4, materials can be evaporated at a desired position of each substrate 14 by snaking the evaporation sources 12a and 12b through the upper portion of each substrate 14. As shown in FIG. 4, it is also possible to laminate a plurality of materials by evaporating a plurality of different materials with two evaporating sources 12a and 12b when the scope of diffusion in the evaporated materials is narrow. Table 3 shows evaporation processes of the deposition apparatus 10d in FIG. 4.

TABLE 1

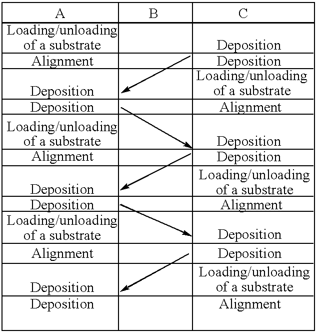

In this example, when the substrate 14 is loaded into and is unloaded from the substrate work chamber 16 or the substrate 14 and the mask are aligned in the same vacuum chamber A (C), evaporation is performed in another vacuum chamber C (A) in the same manner as in Example 1. This can reduce production costs due to few wasteful consumption of the materials.

Furthermore, two evaporation sources 12a and 12b are used, but the number of the evaporation sources may be changed according to the substrates 14 manufactured. The evaporation sources 12a and 12b snake through the upper portion of each substrate 14, but other courses may be taken.

### EXAMPLE 5

A plurality of vacuum chambers A and C are used in any of examples described above, but one vacuum chamber may be used. A plurality of substrates 14 are loaded into and are unloaded in the same vacuum chamber. When one substrate 14 is loaded and unloaded or the substrate 14 and a mask are aligned, evaporation is performed on another substrate 14. Comparing with the above-mentioned examples, the wasteful consumption of the materials is reduced due to no path B.

The above-mentioned gate valve may be arranged and each substrate 14 may be separated when a plurality of substrates 14 are disposed in the same vacuum chamber.

### EXAMPLE 6

The deposition apparatuses 10a, 10b, 10c, and 10d shown in Examples 1 to 4 and the deposition apparatus shown in Example 5 may be used in combination. More specifically, a plurality of substrates 14 are evaporated in each of the vacuum chambers A and C and the evaporation source 12 is transferred between the vacuum chambers A and C.

As described in the above-mentioned examples, the wasteful consumption of materials can be extremely minimized by transferring the evaporation source 12 between the plurality of substrates 14. According to the present invention, material costs can be reduced and the productivity of OLEDs can be improved, which leads to a decrease in production costs.

According to the present invention, it becomes possible to divert the waiting time of an evaporation source (time which is not contributed to evaporation) to the time to evaporate on another substrate because evaporation is performed at a plurality of positions on the substrate by one evaporation source, which leads to a reduction in the amount of the evaporant useless in actual evaporation during the production processes. Thus, the usability of materials can be improved and significant effects are brought about in an increase of productivity and a decrease of production costs.

While the embodiments of the present invention have thus been described with reference to the drawings, it should be understood that the present invention be not limited to the embodiments shown in the drawings. Various changes, modifications, and improvements can be made to the embodiments on the basis of knowledge of those skilled in the art without departing from the scope of the present invention.

This application claims priority from Japanese Patent Application No. 2004-181207, which is incorporated herein by reference.

1. A deposition apparatus for depositing an evaporant on a plurality of substrates comprising:
one or more vacuum chambers where the substrates are arranged; and
an evaporation source for evaporating materials by heating to deposit evaporant on each substrate, wherein the evaporation source is able to move near to at least two of the substrates.

2. The apparatus according to claim 1, wherein a plurality of the substrates are arranged in the one vacuum chamber.

3. The apparatus according to claim 1, wherein a plurality of the substrates are arranged in a plurality of the vacuum chambers,
wherein the adjacent vacuum chambers are spatially connected to each other so that the evaporation source inside the vacuum chambers can move from the one vacuum chamber into the other vacuum chamber.

4. The apparatus according to claim 3, further comprising:
an opening/closing system for spatially separating one of the adjacent vacuum chamber from and connecting the one vacuum chamber to the other vacuum chamber, the opening/closing system being provided at a portion connecting the adjacent vacuum chambers, and wherein the each vacuum chamber is capable of evacuating an atmosphere therein.

5. The apparatus according to claims 1, further comprising:
a means for enable the evaporation source to cycle and/or reciprocate.

6. The apparatus according to claim 1, wherein a plurality of the evaporation sources evaporates different materials respectively.

7. The apparatus according to claim 1, wherein a plurality of the evaporation sources are plural and deposit the evaporant on different substrate respectively.

8. The apparatus according to claim 1, wherein the movements of a plurality of the evaporation sources are synchronized to deposit the evaporant on the same substrate.

9. The apparatus according to claim 1, further comprising means for performing other process on any of the substrates while any other of the substrates is deposited by the evaporation sources.

10. The apparatus according to claim 9, wherein the means for performing other process is to load the substrates into and unload the substrate from the vacuum chambers and/or to align a masks for evaporation with the substrate.

11. The apparatus according to claim 1, wherein the evaporant is organic material.

12. A method for depositing evaporant on a plurality of substrates comprising the steps of: preparing the substrates;
arranging an evaporation source near an one of the substrates;
evaporating the materials by heating to deposit the evaporant on the one substrate;
moving the evaporation source from the one substrate to near an another of the substrates; and
evaporating the materials by heating to deposit the evaporant on the another substrate

13. The method according to claim 12, wherein a plurality of the evaporation sources evaporates different materials respectively.

14. The method according to claim 12, wherein a plurality of the evaporation sources deposit the evaporant on the different substrates respectively.

15. The method according to claim 12, wherein a plurality of the evaporation sources are synchronized to deposit the evaporant on the same substrate.

16. The method according to claim 12, further comprising:
performing the other process on a third substrate while evaporating the materials to deposit the evaporant on the one substrate.

17. The method according to claim 16, wherein the other process is to load and unload the substrate into and from the vacuum chambers and/or to align a mask for evaporation with the substrate.

18. The method according to claim 12, the move of the evaporation source is a circulation movement and/or a reciprocation.
